(19) United States
(12) Patent Application Publication
(10) Pub. No.: US 2025/0277845 A1
(43) Pub. Date: Sep. 4, 2025

(54) TEST BOARD FOR BURN-IN TEST

(71) Applicant: UNITEST INC, Yongin-si (KR)

(72) Inventor: Jang Sik MOON, Hwaseong-si (KR)

(73) Assignee: UNITEST INC, Yongin-si (KR)

(21) Appl. No.: 19/008,312

(22) Filed: Jan. 2, 2025

(30) Foreign Application Priority Data
Mar. 4, 2024 (KR) 10-2024-0030813

(51) Int. Cl. G01R 31/28

(52) U.S. Cl. CPC G01R 31/2863

(57) ABSTRACT

Proposed is a test board for a burn-in test. According to a specific embodiment of the present technology, in a basic-type test board that supplies a test signal of a PGB to sockets of sub-boards, each sub-board is arranged in a single-row single-layer structure on one interface board or FTB, so the height of the test board can be lowered compared to a conventional test board, thereby enabling smooth airflow, and a plurality of semiconductor devices can be tested in a uniform environment, thereby improving the durability of the test board. Furthermore, each sub-board is connected in parallel to the interface board or FTB, so a test signal can be simultaneously supplied to sockets of each sub-board through each sub-connector, thereby enabling high-speed processing. Moreover, each sub-board can be configured in various types and sizes, so the productivity of a test board circuit board can be increased.

### CROSS REFERENCE TO RELATED APPLICATION

The present application claims priority to Korean Patent Application No. 10-2024-0030813, filed Mar. 4, 2024, the entire contents of which is incorporated herein for all purposes by this reference.

### BACKGROUND OF THE INVENTION

### Field of the Invention

The present disclosure relates generally to a test board for a burn-in test. More particularly, the present disclosure relates to a technology in which at least one sub-board is arranged in a single-row single-layer structure on an interface board connected to a feed through board (FTB) or on the FTB in a test board type that sequentially supplies a test signal of a pattern generation board (PGB) to sockets of sub-boards, thereby ensuring temperature uniformity around a semiconductor device during testing and thus enabling a plurality of semiconductor devices to be tested in a uniform environment; and sub-boards of various sizes and types are connected in parallel to the interface board or FTB, thereby improving the productivity of a test board circuit board.

### Description of the Related Art

Semiconductor devices undergo various tests after they are produced. A burn-in test is a test that checks how well semiconductor devices can withstand thermal stress when electrical signals are applied to the semiconductor devices and they are operated. Equipment that performs this burn-in test is called a burn-in tester.

A burn-in tester generally has a burn-in chamber that accommodates semiconductor devices, and a test chamber that accommodates a tester board for reading a result signal fed back after applying a test signal to the semiconductor devices accommodated in the burn-in chamber.

The semiconductor devices are loaded in matrix form on the test board and stored in the burn-in chamber so that a plurality of semiconductor devices can be tested simultaneously. The burn-in chamber has a structure in which a plurality of test boards are stored together to further increase processing capacity.

The semiconductor devices loaded on the test board are electrically connected to the tester board through a socket provided on the test board.

As semiconductor processes become finer and semiconductor packaging technology develops, the ball size and spacing of semiconductor devices become finer. As a result, the ball size and spacing of semiconductor device test sockets applied in matrix form to a large-area interface board become extremely small, which affects the manufacturing quality of a test board circuit board being designed/manufactured. Therefore, there is a need for solving the quality problem.

The foregoing is intended merely to aid in the understanding of the background of the present disclosure, and is not intended to mean that the present disclosure falls within the purview of the related art that is already known to those skilled in the art.

### DOCUMENTS OF RELATED ART

(Patent document 1) Korean Patent Application Publication No. 10-2018-0045917 (published on May 8, 2018)

### SUMMARY OF THE INVENTION

Accordingly, the present disclosure has been made keeping in mind the above problems occurring in the related art, and one objective of the present disclosure is to provide a test board for a burn-in test, in which in a basic-type test board that supplies a test signal from a test substrate to sockets of sub-boards, at least one sub-board is connected to one interface board or feed through board (FTB) in a single-row single-layer structure, thereby ensuring temperature uniformity around a semiconductor device during testing and thus enabling a plurality of semiconductor devices to be tested in a uniform environment.

Another objective of the present disclosure is to provide a test board for a burn-in test, in which sub-boards of various types and sizes are connected in parallel to one interface board or FTB, thereby reducing the manufacturing cost of the test board, and reducing the manufacturing cost of the test board by replacing only a defective sub-board.

The objectives of the present disclosure are not limited to those mentioned above, and other objectives not mentioned and advantages of the present disclosure will become apparent from the following description and will be more clearly understood from the embodiments of the present disclosure. Furthermore, it will be readily apparent that the objectives and advantages of the present disclosure can be realized by means and combinations thereof set forth in the claims.

In order to achieve the above objectives, according to one aspect of the present disclosure, there is provided a test board for a burn-in test, the test board including: at least one interface board including an electrical circuit for applying and transmitting a test signal of a PGB to at least one sub-board; the at least one sub-board having a plurality of sockets on which a plurality of semiconductor devices to be tested are loaded; an interface connector electrically connecting an FTB for transmitting the test signal of the PGB and the at least one interface board to each other; and at least one sub-connector electrically connecting the at least one sub-board to the interface board.

Preferably, the at least one sub-board may include a plurality of sub-boards, and the plurality of sub-boards may be provided in a single-row single-layer structure on the interface board.

Preferably, the at least one sub-board may include a plurality of sub-boards, and the plurality of sub-boards may be connected in parallel to the interface board by a plurality of sub-connectors.

According to another aspect of the present disclosure, there is provided a test board for a burn-in test, the test board including: at least one sub-board having a plurality of sockets on which semiconductor devices to be tested are loaded, and including an electric circuit for receiving a test signal of a PGB transmitted through an FTB and applying the test signal to the plurality of sockets; and at least one connector electrically connecting the at least one sub-board to the FTB.

Preferably, the at least one sub-board may include a plurality of sub-boards, and the plurality of sub-boards may be provided in a single-row single-layer structure on the FTB.

Preferably, the at least one sub-board may include a plurality of sub-boards, and the plurality of sub-boards may be connected in parallel to the FTB by a plurality of sub-connectors.

According to these features, in a basic-type test board that supplies a test signal of a PGB to socket of sub-boards, since each sub-board is arranged in a single-row single-layer structure on one interface board or FTB, the height of the test board can be lowered compared to a conventional test board, thereby enabling smooth airflow, and a plurality of semiconductor devices can be tested in a uniform environment, thereby improving the durability of the test board.

According to the embodiment of the present disclosure, since each sub-board is connected in parallel to one interface board or FTB, a test signal can be simultaneously supplied to sockets of each sub-board through each sub-connector, thereby enabling high-speed processing. This high-speed processing can shorten the time length of a response signal to the test signal, thereby eliminating carrier waves that act as response signal distortion and improving the performance of the test board.

Additionally, according to the embodiment of the present disclosure, since each sub-board can be configured in various types and sizes, the productivity of a test board circuit board can be increased.

### BRIEF DESCRIPTION OF THE DRAWINGS

The accompanying drawings illustrate a preferred embodiment of the present disclosure and together with the foregoing disclosure, serve to provide further understanding of the technical features of the present disclosure, and thus, the present disclosure is not construed as being limited to the drawings, in which:

FIG. 1 is a side view illustrating a test board for a burn-in test according to an embodiment;

FIG. 2 is a front view illustrating the test board illustrated in FIG. 1;

FIG. 3 is a side view illustrating a test board for a burn-in test according to another embodiment; and

FIG. 4 is a front view illustrating the test board illustrated in FIG. 3.

### DETAILED DESCRIPTION OF THE INVENTION

Hereinbelow, an exemplary embodiment of the present disclosure will be described in detail with reference to the accompanying drawings such that the present disclosure can be easily embodied by one of ordinary skill in the art to which the present disclosure belongs. The embodiment of the present disclosure may be changed to a variety of embodiments and the scope and spirit of the present disclosure are not limited to the embodiment described hereinbelow. Wherever possible, the same reference numbers will be used throughout the drawings to refer to the same or like parts, and parts irrelevant to the description of the present disclosure have been omitted.

One embodiment below specifically describes a configuration in which at least one sub-board is arranged in a single row single layer structure on one interface board or FTB, so the height of a test board is lowered compared to a conventional test board, thereby improving airflow and maintaining temperature uniformity of the test board, and thus, even when heat is generated from a semiconductor device during testing of the semiconductor device, the semiconductor device can be tested in a uniform temperature environment.

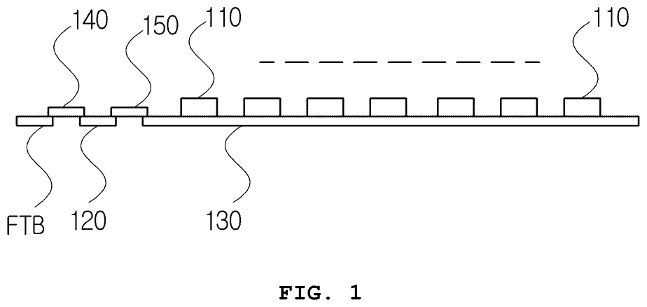

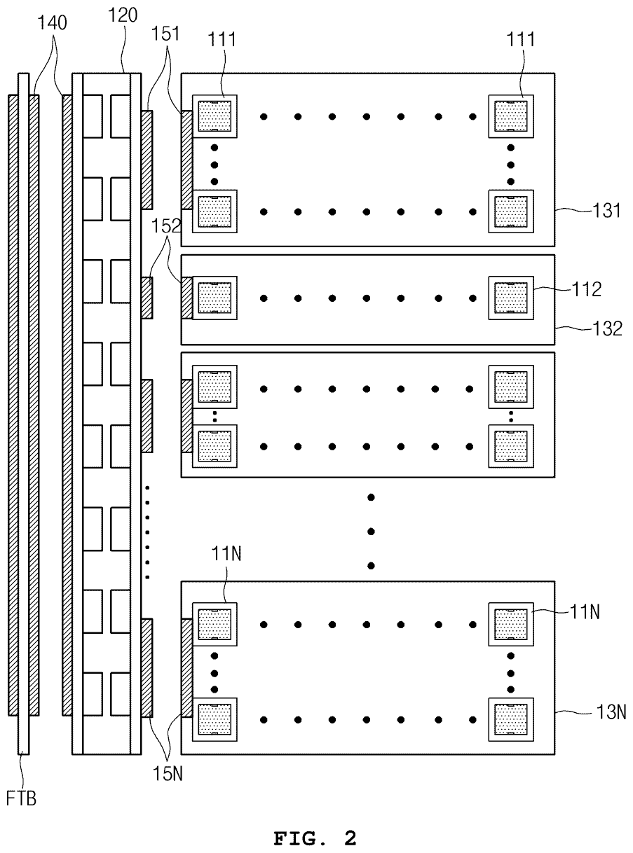

FIG. 1 is a side view illustrating a test board for a burn-in test according to an embodiment, and FIG. 2 is a front view illustrating the test board illustrated in FIG. 1. Referring to FIGS. 1 and 2, the test board according to the embodiment has a configuration that implements a lower height of the test board compared to a conventional test board by connecting at least one sub-board to one interface board in a single-row single-layer structure in parallel. Therefore, the test board for the burn-in test may include a plurality of sockets (110 in FIGS. 1, 111 to 11N in FIG. 2), an interface board 120, at least one sub-board (130 in FIGS. 1, 131 to 13N in FIG. 2), an interface connector 140, and at least one sub-connector (150 in FIGS. 1, 151 to 15N in FIG. 2). Here, N is at least one natural number.

The plurality of sockets 111 to 11N allow a plurality of semiconductor devices to be tested to be loaded thereon, respectively, and may be arranged in matrix form.

The interface board 120 includes an electric circuit having transmission line groups for applying a received test signal of a PGB to the plurality of sockets 111 to 11N. Here, the interface board 120 and the sub-boards 131 to 13N are arranged in a single-layer structure. Here, as illustrated in FIG. 2, the sub-boards 131 to 13N may have various types and sizes.

Meanwhile, each of the sub-boards 131 to 13N includes an electrical circuit having a transmission line group for applying a test signal of the interface board 120 to the plurality of sockets 111 to 11N. That is, a test signal (operation signal of a semiconductor device) of the PGB supplied through an FTB is applied to the plurality of semiconductor devices respectively loaded on the plurality of sockets 111 to 11N, and a response signal fed back according to the operation of the semiconductor devices is transmitted to the interface board 120.

The interface connector 140 may electrically connect the FTB and the interface board 120 to each other. Each of the sub-connectors 151 to 15N may electrically connect the interface board 120 and each of the sub-boards 131 to 13N to each other.

Accordingly, the test (operation) signal is supplied to a plurality of sockets of each of the sub-boards 131 to 13N via the interface connector 140, the interface board 120, and each of the sub-connectors 151 to 15N.

Additionally, each of the sub-boards 131 to 13N may return the test signal. In another example, each of the sub-boards 131 to 13N may branch the test signal and deliver it to sockets of corresponding row.

Accordingly, in the embodiment, the interface board 120 and the sub-boards 131 to 13N are connected in parallel in a single-row single layer structure, so the height of the test board is lowered compared to a conventional test board, thereby maintaining the temperature uniformity of the semiconductor device, and even when heat is generated from the semiconductor device during testing, the semiconductor device can be tested in a more uniform temperature environment.

Here, a board that returns the test signal and a board that branches the test signal and transmits it to the sockets of the corresponding row may be provided as separate devices from the sub-boards 131 to 13N, or may be formed integrally with one sub-board 131, but the present disclosure is not limited thereto.

Therefore, the test signal may be returned or branched by the sub-boards 131 to 13N and transmitted to the plurality of sockets 111 to 11N.

Accordingly, in the embodiment of the present disclosure, since the test signal is simultaneously supplied to the sub-boards through the sub-connectors connected in parallel to one interface board, high-speed processing of data is possible. This high-speed processing can shorten the time length of the response signal to the test (operation) signal, thereby eliminating carrier waves that act as response signal distortion and improving the performance of the test board.

Additionally, since the sub-boards 131 to 13N are configured in various types and sizes, the productivity of a test board circuit board can be increased.

One embodiment of the present disclosure relates to a basic-type test board that is electrically connected to a test substrate to supply a test signal to sockets of sub-boards having a multi-layer structure (at least two layers), in which an interface board and the sub-boards are arranged in a single-row single-layer structure, thereby enabling smooth airflow due to a lower height of the test board compared to a conventional test board.

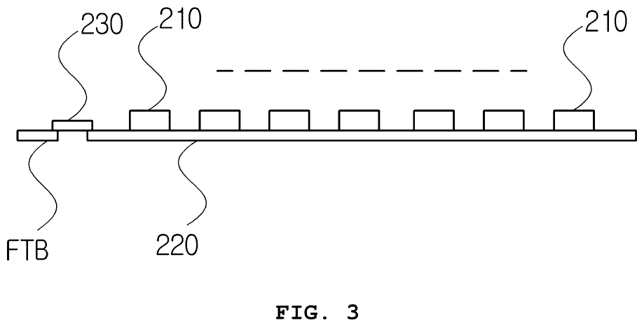

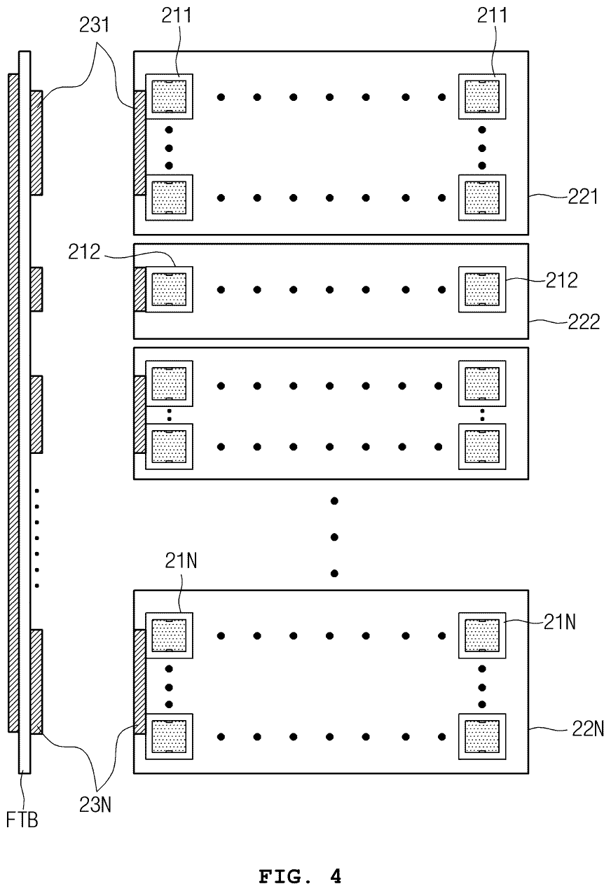

FIG. 3 is a side view illustrating a test board for a burn-in test according to another embodiment, and FIG. 4 is a front view illustrating the test board illustrated in FIG. 3. Referring to FIGS. 3 and 4, the test board according to the other embodiment includes a plurality of sockets 211 to 21N, at least one sub-board 221 to 22N, and at least one connector 231 to 23N.

The plurality of sockets 211 to 21N allow a plurality of semiconductor devices to be tested to be loaded thereon, respectively, and may be arranged in matrix form on the sub-boards 221 to 22N.

Each of the sub-boards 221 to 22N includes an electric circuit having a transmission line group for applying a test signal (operation signal of a semiconductor device) of a PGB supplied through an FTB to the plurality of semiconductor devices respectively loaded on the plurality of sockets 211 to 21N and for transmitting a response signal fed back according to the operation of the semiconductor devices to the FTB.

Meanwhile, each of the connectors 231 to 23N may electrically connect the FTB and each of the sub-boards 221 to 22N to each other in parallel.

Therefore, when the test (operation) signal is applied to the semiconductor devices to be tested, the test signal is provided to sockets 210 of a matrix structure of the sub-boards 221 to 22N via the connectors 231 to 23N, and a test (operation) of a semiconductor device loaded on each of the sockets 210 is performed.

Accordingly, in the embodiment, since the sub-boards 221 to 22N are arranged on the FTB in a single-row single-layer structure, the height of the test board that occupies a chamber space is lowered compared to a conventional test board. Therefore, the test (operation) of the semiconductor device is performed in a state where the temperature uniformity around the semiconductor device can be maintained, thereby improving the durability of the test board.

Additionally, in the embodiment, since the sub-boards 221 to 22N are connected in parallel to the FTB, the test signal is supplied to the semiconductor devices of the sub-boards 221 to 22N simultaneously, thereby enabling high-speed processing of data. This high-speed processing can shorten the time length of the response signal to the test (operation) signal, thereby eliminating carrier waves that act as response signal distortion and improving the performance of the test board.

Additionally, since the sub-boards 221 to 22N are configured in various types and sizes, the productivity of a test board circuit board can be increased.

While the present disclosure has been described with reference to a certain exemplary embodiment thereof, those skilled in the art will and appreciate that various modifications, additions, substitutions are possible, without departing from the scope and spirit of the present disclosure as disclosed in the accompanying claims. For example, suitable results may be achieved if the described techniques are performed in a different order and/or if components in a described system, architecture, device, or circuit are combined in a different manner and/or replaced or supplemented by other components or equivalents.

Therefore, the scope of the present disclosure should not be limited to the above-described exemplary embodiment but should be determined by not only the appended claims but also the equivalents thereof.

What is claimed is:

1. A test board for a burn-in test, the test board comprising:
at least one interface board including an electrical circuit for applying and transmitting a test signal of a PGB to at least one sub-board;
the at least one sub-board having a plurality of sockets on which a plurality of semiconductor devices to be tested are loaded;
an interface e connector electrically connecting an FTB for transmitting the test signal of the PGB and the at least one interface board to each other; and
at least one sub-connector electrically connecting the at least one sub-board to the interface board.

2. The test board of claim 1, wherein the at least one sub-board comprises a plurality of sub-boards, and the plurality of sub-boards are provided in a single-row single-layer structure on the interface board.

3. The test board of claim 1, wherein the at least one sub-board comprises a plurality of sub-boards, and the plurality of sub-boards are connected in parallel to the interface board by a plurality of sub-connectors.

4. A test board for a burn-in test, the test board comprising:
at least one sub-board having a plurality of sockets on which semiconductor devices to be tested are loaded, and including an electric circuit for receiving a test signal of a PGB transmitted through an FTB and applying the test signal to the plurality of sockets; and
at least one connector electrically connecting the at least one sub-board to the FTB.

5. The test board of claim 4, wherein the at least one sub-board comprises a plurality of sub-boards, and the plurality of sub-boards are provided in a single-row single-layer structure on the FTB.

6. The test board of claim 4, wherein the at least one sub-board comprises a plurality of sub-boards, and the plurality of sub-boards are connected in parallel to the FTB by a plurality of sub-connectors.
